(19) United States
(12) Patent Application Publication
(10) Pub. No.: US 2012/0012876 A1
(43) Pub. Date: Jan. 19, 2012

(54) LIGHT EMITTING DEVICE

(75) Inventor: Masaaki KATOH, Osaka-shi (JP)

(73) Assignee: SHARP KABUSHIKI KAISHA, Osaka-shi (JP)

(21) Appl. No.: 13/182,224

(22) Filed: Jul. 13, 2011

(30) Foreign Application Priority Data
Jul. 14, 2010 (JP) 2010-159621

(51) Int. Cl. H01L 33/60

(52) U.S. Cl. 257/98; 257/E33.058

(57) ABSTRACT

The present invention provides a light emitting device which can be improved in reliability and moreover which can be manufactured with low cost. A surface-mount type light emitting device 100 includes a substrate 10, a interconnect pattern 20 provided on the substrate 10, a semiconductor light emitting element 30 mounted on the substrate 10 and electrically connected to the interconnect pattern 20, a dome-shaped phosphor-containing sealing resin 40 for sealing the semiconductor light emitting element 30, a reflector 50 attached to the substrate 10 and having an opening 51 which overlaps with the semiconductor light emitting element 30 in a plan view, and a liquid-repelling layer 60 which covers an inner wall surface of the opening 51 of the reflector 50 and part of which is in contact with the dome-shaped phosphor-containing sealing resin 40.

### TECHNICAL FIELD

The present invention relates to light emitting devices such as surface-mount type light emitting devices in which an LED (Light Emitting Device)-mounted package is coated with a liquid-repelling coating material. In particular, the invention relates to a light emitting device excellent in reliability and productivity.

### BACKGROUND ART

A prior-art light emitting device is disclosed in JP 2002-223005 A (Patent Literature 1). This light emitting device, as shown in FIG. 13, includes a first lead 1001, a second lead 1002, a light emitting element 1003 mounted on one end portion of the first lead 1001, and a transparent epoxy resin 1004 for sealing the light emitting element 1003.

A light emitting surface 1004a (convex lens) for radiating emitted light of the light emitting element 1003 is provided on top of the transparent epoxy resin 1004.

One end portion of the second lead 1002 is electrically connected to the light emitting element 1003 via a wire 1006.

The light emitting device also includes a black epoxy resin 1005 which covers lower part of the transparent epoxy resin 1004. A light-shielding wall 1005a is provided on a peripheral portion of the black epoxy resin 1005 so as to increase an upper end height of the outer periphery of the black epoxy resin 1005. As a result, in manufacture of display devices with this light emitting device arranged in plurality, liquid level control of weather-resistant resin to be filled between those light emitting devices becomes easier to achieve.

Another prior-art light emitting device is disclosed in JP 2005-317661 A (Patent Literature 2). This light emitting device, as shown in FIG. 14, includes an LED element 2001, a metallic first lead frame 2002 on which the LED element 2001 is to be mounted, a metallic second lead frame 2003 which is to be electrically connected to the LED element 2001 via a wire 2006, a transparent resin portion 2004 provided on the LED element 2001, and a light-shielding resin portion 2005 which surrounds peripheries of the LED element 2001 and the transparent resin portion 2004 and which is higher in reflectivity than the transparent resin portion 2004.

The transparent resin portion 2004 has a lens portion formed by a transfer molding method to form a lens on the LED element 2001, and a holding portion 2004b for holding the first lead frame 2002 and the second lead frame 2003. As a result of this, it becomes achievable to downsize the light emitting device while enough strength of the first lead frame 2002 and the second lead frame 2003 is ensured.

In one aspect, the prior-art light emitting device shown in FIG. 13 is increased in contact area between the transparent epoxy resin 1004 and the black epoxy resin 1005. Therefore, peeling of the transparent epoxy resin 1004 more easily occurs due to differences in coefficient of thermal expansion between the transparent epoxy resin 1004 and the black epoxy resin 1005.

As a consequence, the prior-art light emitting device incurs more faults, thus having an issue of poorer reliability.

Also, the another prior-art light emitting device shown in FIG. 14, the transparent resin portion 2004 of which is molded by a transfer molding method, involves higher expenses for equipment and metal molds for obtaining the transparent resin portion 2004.

That is, the another prior-art light emitting device has an issue of increased manufacturing cost.

Furthermore, since cracks easily occur near the border between resin and metal due to differences in coefficient of thermal expansion between the resin and the metal, there is a need for carefully selecting a wall thickness of the transparent resin portion 2004 and materials of the metallic first lead frame 2002 and the second lead frame 2003.

### SUMMARY OF INVENTION

### Technical Problem

Accordingly, an object of the present invention is to provide a light emitting device which can be improved in reliability and moreover which can be manufactured with low cost.

### Solution to Problem

In order to achieve the above object, there is provided a light emitting device comprising:

a substrate;

an interconnect pattern provided on the substrate;

a semiconductor light emitting element mounted on the substrate and electrically connected to the interconnect pattern;

a sealing resin for sealing the semiconductor light emitting element;

a reflector provided on the substrate and having an opening which overlaps with the semiconductor light emitting element in a plan view; and

a liquid-repelling layer which covers an inner wall surface of the opening of the reflector and at least part of which is in contact with the sealing resin.

With the above-described construction, since the liquid-repelling layer covers the inner wall of the opening of the reflector, the sealing resin can be prevented from making contact with the reflector, so that peeling of the sealing resin can be prevented even with large differences in coefficient of thermal expansion or the like between the sealing resin and the reflector. Thus, faults due to the peeling of the sealing resin can be reduced and therefore the reliability can be improved.

Also, since at least part of the liquid-repelling layer is in contact with the sealing resin, the sealing resin has larger contact angles to the liquid-repelling layer by liquid-repelling effect in portions in contact with the liquid-repelling layer. Therefore, the sealing resin can be formed into, for example, a dome shape without using any metal mold. Thus, the light emitting device can be manufactured with low cost.

Further, providing the reflector makes it possible to pick up an outer peripheral portion of the reflector as an example, so that the sealing resin and the liquid-repelling layer positioned inside the reflector can be prevented from being damaged.

Also, the angle formed by the side surface of the peripheral edge portion of the sealing resin to one surface of the substrate on one side closer to the semiconductor light emitting element can be adjusted not only by wettability of the liquid-repelling layer but also by adding an inclination angle of the inner wall of the opening of the reflector to the substrate surface on the semiconductor light emitting element side.

In one embodiment of the invention, an end-portion inner surface of the liquid-repelling layer on one side closer to the substrate is vertical or generally vertical to one surface of the substrate closer to the semiconductor light emitting element, and is in contact with a peripheral edge portion of the sealing resin.

According to this embodiment, the inner surface of the substrate-side end portion of the liquid-repelling layer is in contact with the peripheral edge portion of the sealing resin. In this case, since the inner surface of the substrate-side end portion of the liquid-repelling layer is vertical or generally vertical to the semiconductor light emitting element side surface of the substrate, the angle of the side face of the peripheral edge portion of the sealing resin to the bottom surface (substrate-side surface) of the sealing resin can easily be set to 90° or nearly 90°.

Accordingly, by surface tension of the sealing resin, the sealing resin can be made to serve as a resin lens of high curvature.

If the inner surface of the substrate-side end portion of the liquid-repelling layer is inclined with respect to the semiconductor light emitting element-side surface of the substrate, then the verticality of the peripheral edge portion of the sealing resin with respect to the bottom surface (substrate-side surface) of the sealing resin is declined.

In addition, the inner wall of the substrate-side end portion of the opening of the reflector may also be vertical or generally vertical to the semiconductor light emitting element-side surface of the substrate. When the inner wall of the substrate-side end portion of the opening of the reflector is also set vertical or generally vertical to the semiconductor light emitting element-side surface of the substrate, it becomes more easily achievable to set the inner surface of the substrate-side end portion of the liquid-repelling layer vertical or generally vertical to the semiconductor light emitting element-side surface of the substrate.

In one embodiment of the invention, the sealing resin includes at least one of a light-pervious resin which is pervious to emitted light of the semiconductor light emitting element and a resin containing a phosphor.

According to this embodiment, when the sealing resin contains a light-pervious resin which is pervious to emitted light of the semiconductor light emitting element, declines of the light extraction efficiency of the emitted light of the semiconductor light emitting element can be prevented.

Further, when the sealing resin contains a phosphor-containing resin, the phosphor can be excited by emitted light of the semiconductor light emitting element, allowing the phosphor to emit light different in wavelength from the emitted light.

The phosphor may be dispersed uniformly in the sealing resin or settled in low part of the sealing resin, i.e., near the semiconductor light emitting element.

In one embodiment of the invention, the liquid-repelling layer is formed from a fluorine-based resin.

According to this embodiment, usable as the material of the liquid-repelling layer are such fluorine-based resins as PTFE (polytetrafluoroethylene (4-fluoride)), PFA (tetrafluoroethylene-perfluoroalkylvinylether copolymer), FEP (tetrafluoroethylene-hexafluoropropylene copolymer (4.6-fluoride)), ETFE (tetrafluoroethylene-ethylene copolymer), PVDF (polyvinylidene fluoride (2-fluoride)), PCTFE (polychlorotrifluoroethylene (3-fluoride)), and the like. With use of such a fluorine-based resin as the material of the liquid-repelling layer, enough liquid-repelling effect in the liquid-repelling layer can be obtained.

In one embodiment of the invention, the sealing resin is surrounded by the liquid-repelling layer.

According to this embodiment, since the sealing resin is surrounded by the liquid-repelling layer, the sealing resin can be formed into, for example, a dome shape without using any metal mold.

In one embodiment of the invention, the liquid-repelling layer has a first liquid-repelling layer, a second liquid-repelling layer provided between the first liquid-repelling layer and the semiconductor light emitting element.

According to this embodiment, a so-called double sealing resin can easily be formed by the first liquid-repelling layer and the second liquid-repelling layer.

### ADVANTAGEOUS EFFECTS OF INVENTION

According to the light emitting device of the invention, the light emitting device includes a sealing resin for sealing the semiconductor light emitting element, a reflector provided on the substrate and having an opening which overlaps with the semiconductor light emitting element in a plan view, and a liquid-repelling layer which covers an inner wall of the opening of the reflector and at least part of which is in contact with the sealing resin. Therefore, the sealing resin can be prevented from making contact with the reflector, so that peeling of the sealing resin can be prevented even with large differences in coefficient of thermal expansion or the like between the sealing resin and the reflector. Thus, faults due to the peeling of the sealing resin can be reduced and therefore the reliability can be improved.

Also, since at least part of the liquid-repelling layer is in contact with the sealing resin, the sealing resin has larger contact angles to the liquid-repelling layer. Therefore, the sealing resin can be formed into, for example, a dome shape without using any metal mold. Thus, the light emitting device can be manufactured with low cost.

### BRIEF DESCRIPTION OF DRAWINGS

The present invention will become more fully understood from the detailed description given hereinbelow and the accompanying drawings which are given by way of illustration only, and thus are not intended to limit the present invention, and wherein:

FIG. 1 is a schematic sectional view of a surface-mount type light emitting device according to a first embodiment of the invention;

FIG. 2 is a schematic plan view of the surface-mount type light emitting device according to the first embodiment;

FIG. 3A is a process view of a manufacturing method of the surface-mount type light emitting device according to the first embodiment;

FIG. 3B is a process view of the manufacturing method of a rod-like structure light emitting device subsequent to FIG. 3A;

FIG. 3C is a schematic perspective view of a reflector of the surface-mount type light emitting device according to the first embodiment;

FIG. 3D is a process view of the manufacturing method of the rod-like structure light emitting device subsequent to FIG. 3B;

FIG. 3E is a process view of the manufacturing method of the rod-like structure light emitting device subsequent to FIG. 3D;

FIG. 3F is a process view of the manufacturing method of the rod-like structure light emitting device subsequent to FIG. 3E;

FIG. 4 is a schematic perspective view of the surface-mount type light emitting device according to the first embodiment;

FIG. 5 is a schematic sectional view of a surface-mount type light emitting device according to a second embodiment of the invention;

FIG. 6 is a schematic plan view of the surface-mount type light emitting device according to the second embodiment;

FIG. 7 is a schematic sectional view of a surface-mount type light emitting device according to a third embodiment of the invention;

FIG. 8 is a schematic plan view of the surface-mount type light emitting device according to the third embodiment;

FIG. 9 is a schematic sectional view of a surface-mount type light emitting device according to a modification of the third embodiment;

FIG. 10 is a schematic plan view of a surface-mount type light emitting device according to a fourth embodiment of the invention;

FIG. 11 is a schematic sectional view taken along the line F11-F11 of FIG. 10;

FIG. 12 is a schematic sectional view taken along the line F12-F12 of FIG. 10;

FIG. 13 is a sectional view of a light emitting device according to a prior art; and

FIG. 14 is a sectional view of another light emitting device according to a prior art.

### DESCRIPTION OF EMBODIMENTS

Hereinbelow, embodiments of the present invention will be described with reference to the accompanying drawings. In the drawings referenced below, like or corresponding component members will be designated by like reference numerals without repeating of their description. Further, in FIGS. 2, 3C, 4, 6, 8 and 10, hatching is given not for depiction of cross sections but for easier understanding of correspondence to other drawings.

### First Embodiment

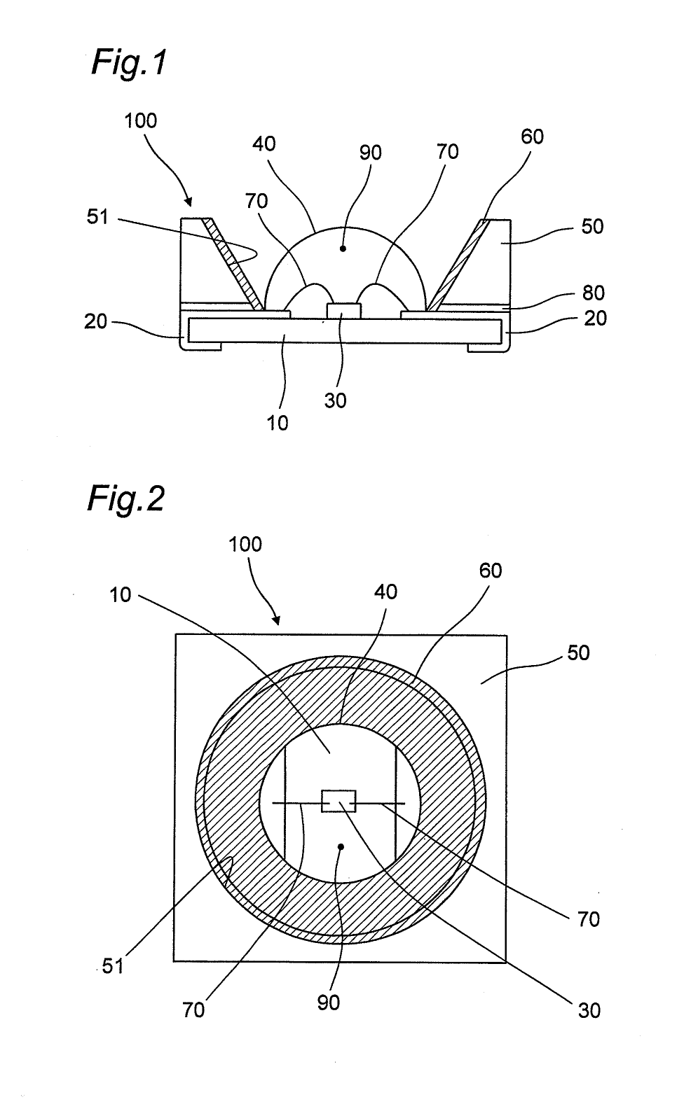

FIG. 1 shows a schematic sectional view of a surface-mount type light emitting device 100 according to a first embodiment of the invention, as it is cut by a plane vertical to a top surface of a substrate 10. FIG. 2 shows a schematic view of the surface-mount type light emitting device 100 as it is viewed from above.

The surface-mount type light emitting device 100, as shown in FIGS. 1 and 2, includes a substrate 10, a metallic interconnect pattern 20 provided on the substrate 10, a semiconductor light emitting element (semiconductor LED (Light Emitting Diode) chip) 30 mounted on the substrate 10, a dome-shaped phosphor-containing sealing resin 40 for sealing the semiconductor light emitting element 30, a reflector 50 attached to the substrate 10 and having an opening 51 which overlaps with the semiconductor light emitting element 30 in a plan view, and a liquid-repelling layer 60 which covers an inner wall surface of the opening 51 of the reflector 50. It is noted that the dome-shaped phosphor-containing sealing resin 40 is an example of the sealing resin of the present invention.

The substrate 10 is formed from, for example, ceramics into a platy shape. A rear face of the semiconductor light emitting element 30 is adhesively fixed to a top surface of the substrate 10. The top face of the substrate 10, to which the semiconductor light emitting element 30 is adhesively fixed, is overlapped with most part of the interconnect pattern 20. In addition, the substrate 10 is preferably made from a material having a coefficient of thermal expansion and a coefficient of thermal contraction close to the coefficient of thermal expansion and the coefficient of thermal contraction of the dome-shaped phosphor-containing sealing resin 40.

The interconnect pattern 20 is composed of a portion extending along the surface of the substrate 10, portions extending along side faces of the substrate 10, and a portion protruding from a side face of the substrate 10 in a direction parallel to the surface of the substrate 10. An adhesive sheet 80 is stacked on a portion of the interconnect pattern 20 extending along the surface of the substrate 10. Although not shown, this adhesive sheet 80 is stacked also on the surface of the substrate 10.

The semiconductor light emitting element 30 is electrically connected to one end portion of the interconnect pattern 20 via a wire 70.

The dome-shaped phosphor-containing sealing resin 40, having a nearly hemispherical face, holds phosphor 90 (only one piece is shown in FIGS. 1 and 2) uniformly dispersed. Also, since the liquid-repelling layer 60 is present between the dome-shaped phosphor-containing sealing resin 40 and the reflector 50, the dome-shaped phosphor-containing sealing resin 40 is not in contact with the reflector 50. It is noted that the dome-shaped phosphor-containing sealing resin 40 also may have a hemispherical face.

The reflector 50 is adhesively bonded to the substrate 10 and the interconnect pattern 20 by the adhesive sheet 80. Also, the inner wall surface of the opening 51 of the reflector 50 is a conical surface inclined against the thicknesswise direction of the substrate 10, and the space in the opening 51 gradually expands from lower side in FIG. 1 to upper side in FIG. 1.

The liquid-repelling layer 60, which is formed along the inner wall surface of the opening 51, has a lower end portion in contact with a foot portion of the dome-shaped phosphor-containing sealing resin 40.

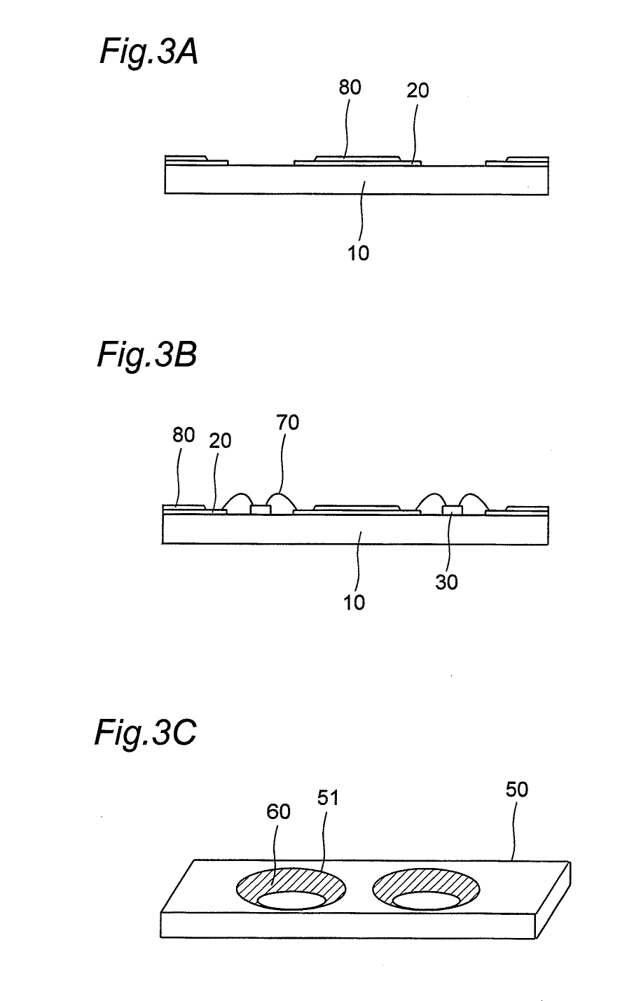

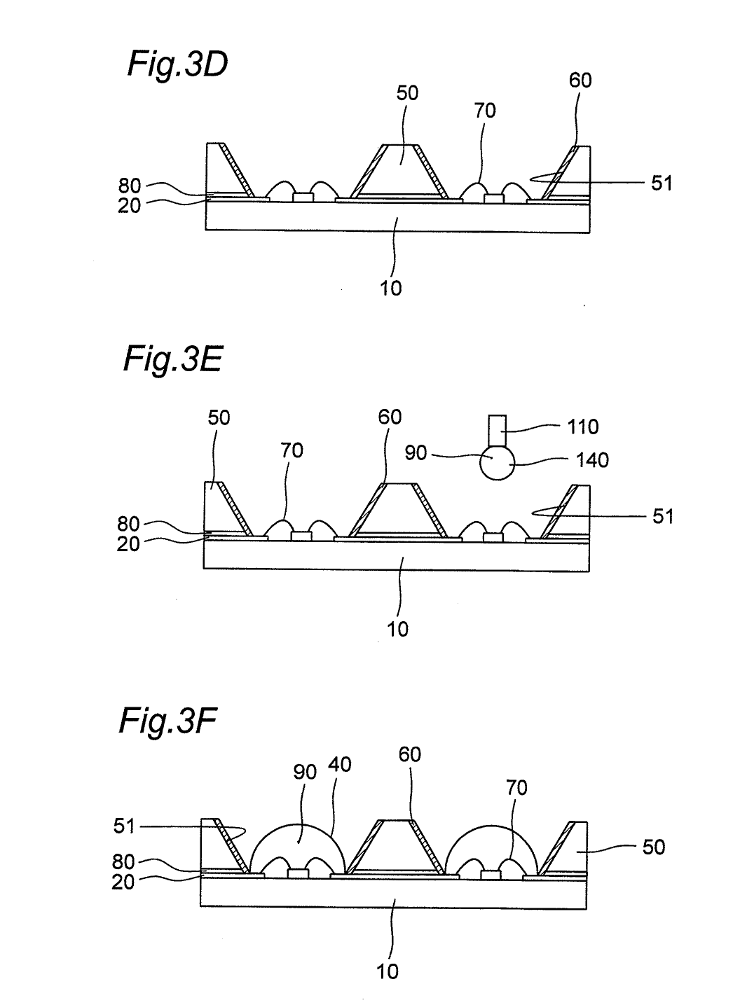

Now, a manufacturing method of the surface-mount type light emitting device 100 will be described below with reference to FIGS. 3A to 3F.

First, as shown in FIG. 3A, a plurality of interconnect patterns 20 are formed with specified spacings on a surface of the substrate 10. These plurality of interconnect patterns 20 are arrayed in one direction parallel to the surface of the substrate 10. Also, each of the interconnect patterns 20 is formed by a 70 μm thick gold layer as an example.

Next, an adhesive sheet 80 is stacked on the surface of the substrate 10 and on specified portions of the interconnect patterns 20.

Next, a semiconductor light emitting element 30 is die-bonded to the surface of the substrate 10 between the interconnect patterns 20.

The semiconductor light emitting element 30 is a blue-color semiconductor light emitting element which is formed from gallium nitride-based compound semiconductor and which has P and N electrodes on one side (upper side in FIGS. 1 and 3B), being formed in chip form. Emitted light of this semiconductor light emitting element 30 is blue-color light having a peak wavelength of 450 nm.

Next, wire bonding is performed on the interconnect patterns 20 and the semiconductor light emitting element 30 so that the semiconductor light emitting element 30 is electrically connected to the interconnect patterns 20 by the wire 70.

Next, a reflector 50 shown in FIG. 3C is mounted on the substrate 10, as shown in FIG. 3D, so as to be integrated with the substrate 10.

In the reflector 50, which is made from Al (aluminum), a mortar-shaped opening 51 is formed so as to have a minimum inner diameter of about 2 mm and a maximum inner diameter of about 3 mm as an example. A coating material is applied to the inner wall surface of this opening 51, and the coating material is dried to form a liquid-repelling layer 60. In this process, the liquid-repelling layer 60, when having a film thickness of 1 μm and a substantial permeability of 95%, allows enough light amount to reach the inner wall surface of the opening 51.

The coating material can be obtained by, for example, adding a fluorine polymer to an acetone solvent. The fluorine polymer is easily solved when added to an acetone solvent and stirred. Also, the acetone solvent in which the fluorine polymer is solved has a moderate viscosity. When the acetone solvent having a moderate viscosity is applied by spraying as a coating material to the inner wall surface of the opening 51 and then cured by drying, a liquid-repelling layer 60 is obtained. In this process, whereas the applied coating is dried and cured after completion of the application of the acetone solvent, this drying may be achieved by leaving the coating at normal temperature but may also be done by using an oven as required.

Usable as materials of the liquid-repelling layer 60 are PTFE (polytetrafluoroethylene (4-fluoride)), PFA (tetrafluoroethylene-perfluoroalkylvinylether copolymer), FEP (tetrafluoroethylene-hexafluoropropylene copolymer (4.6-fluoride)), ETFE (tetrafluoroethylene-ethylene copolymer), PVDF (polyvinylidene fluoride (2-fluoride)), PCTFE (polychlorotrifluoroethylene (3-fluoride)), and the like. Ketone solvents for solving those materials include, for example, acetone, methyl ethyl ketone, diethyl ketone, methyl isobutyl ketone, and the like, while ester solvents include, for example, methyl acetate, ethyl acetate, butyl acetate, and the like.

Next, as shown in FIG. 3E, a forward end of a dispenser 110 is inserted into the opening 51, and a sealing resin 140 is dripped from this forward end. Then, since the inner wall surface of the opening 51 is covered with the liquid-repelling layer 60, the dripped sealing resin 140 comes into contact with the liquid-repelling layer 60 so as to be formed into a dome shape on the substrate 10.

Phosphor 90 (only one piece is shown) is mixed in the sealing resin 140. This phosphor 90, which is excited by emitted light of the semiconductor light emitting element 30, emits light different in wavelength from the emitted light. More specifically, the phosphor 90 emits yellowish light. By light mixing of this yellowish light and blue-color light that is emitted light of the semiconductor light emitting element 30, whitish light can be obtained.

Further, the sealing resin 140 is preferably a low-viscosity, light-pervious liquid resin having high transmissivity to the emitted light of the semiconductor light emitting element 30. In this first embodiment, silicone resin is used as the low-viscosity, liquid sealing resin 140 having high transmissivity to the emitted light of the semiconductor light emitting element 30.

Preferable phosphors to be dispersedly held in the sealing resin 140 include, for example, BOSE (Ba, O, Sr, Si, Eu) or the like. Also preferably usable as the phosphor in addition to BOSE are SOSE (Sr, Ba, Si, O, Eu), YAG (Ce-activated yttrium-aluminum-garnet), α SIALON ((Ca), Si, Al, O, N, Eu), β SIALON (Si, Al, O, N, Eu) and the like.

Next, the sealing resin 140 is heat cured. More specifically, the sealing resin 140 may be cured for several minutes in an 80° C.-150° C. oven as an example.

Next, the substrate 10 is subjected to after-curing under a high-temperature condition. More specifically, the substrate 10 may be subjected to a 5-hour after-curing in a 150° C. oven as an example. By this process, the dome-shaped phosphor-containing sealing resin 40 can be obtained on the substrate 10 as shown in FIG. 3F.

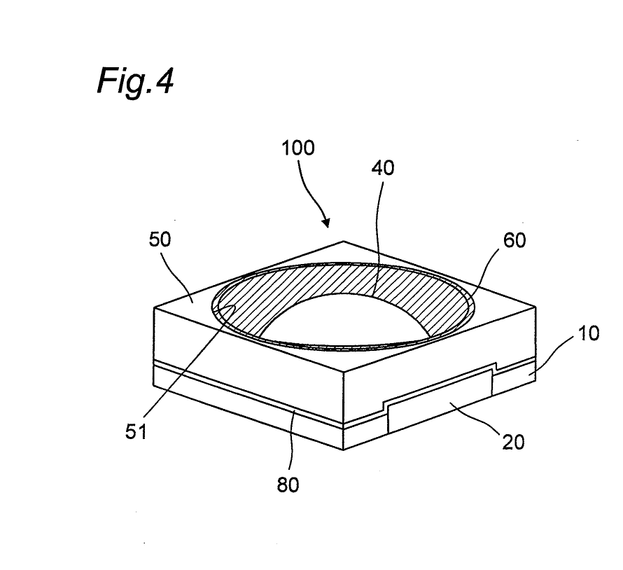

Finally, the substrate 10 is diced together with the reflector 50, by which a plurality of surface-mount type light emitting devices 100 as shown in FIG. 4 can be obtained. In this surface-mount type light emitting device 100, the reflector 50 that surrounds the dome-shaped phosphor-containing sealing resin 40 reflects part of whitish light emitted from the surface of the dome-shaped phosphor-containing sealing resin 40 upward as seen in FIG. 4.

Since the dome-shaped phosphor-containing sealing resin 40 is not in contact with the reflector 50, the dome-shaped phosphor-containing sealing resin 40 can be prevented from occurrence of peeling even if expansion and contraction of the dome-shaped phosphor-containing sealing resin 40 is caused by heat generated from the semiconductor light emitting element 30. As a result, the light emitting device 100 can be reduced in faults, and thus improved in reliability.

Besides, since the dome-shaped phosphor-containing sealing resin 40 can be prevented from occurrence of peeling, the substrate 10 and the reflector 50 may be made from materials different in coefficient of thermal expansion from each other.

Also, since no metal mold is used for the formation of the dome-shaped phosphor-containing sealing resin 40 as described above, the manufacturing cost of the surface-mount type light emitting device 100 can be reduced to a low one.

For making of a light emitting device in which the reflector 50 is eliminated from the surface-mount type light emitting device 100, there may occur defects of damage (e.g., dents) or the like on the surface of the dome-shaped phosphor-containing sealing resin 40 due to contact of workers, jigs or the like with the dome-shaped phosphor-containing sealing resin 40 in the making of this light emitting device. As a result, there may occur failures of declines in optical output and differences in chromaticity in the surface-mount type light emitting device 100.

Also in the work of mounting the light emitting device on other devices by the worker, there may occur failures such as damage (e.g., dents) caused by tweezers or the like on the surface of the dome-shaped phosphor-containing sealing resin 40.

Contact of the tweezers or the like with the surface of the dome-shaped phosphor-containing sealing resin 40 causes cut or peeling of the wire 70, giving rise to a failure that electrical connection between the interconnect patterns 20 and the semiconductor light emitting element 30 is lost. This failure leads to non-lighting of the light emitting device.

In contrast to this, in the surface-mount type light emitting device 100 including the reflector 50, damage or the like on the surface of the dome-shaped phosphor-containing sealing resin 40 can be prevented by the reflector 50 during the making of the surface-mount type light emitting device 100 as well as during the mounting of the surface-mount type light emitting device 100 on other devices. Accordingly, it becomes possible to reduce failures such as declines in optical output and differences in chromaticity of the surface-mount type light emitting device 100 as well as non-lighting of the surface-mount type light emitting device 100 due to cuts or peeling of the wire 70.

In the surface-mount type light emitting device 100 of this first embodiment, one semiconductor light emitting element 30 is included, but a plurality of semiconductor light emitting elements may be included. When these plurality of semiconductor light emitting elements have emitted light of one same color, a light emitting device including those plurality of semiconductor light emitting elements can be provided as a high-output light source. Also, under the condition that a fabricated light emitting device includes a blue-color semiconductor light emitting element having blue emitted light, a green-color semiconductor light emitting element having green-color emitted light, and a red-color semiconductor light emitting element having red-color emitted light, then emitted light of the light emitting device can be toned to white or other light by adjusting current distributions to the blue-color semiconductor light emitting element, the green-color semiconductor light emitting element and the red-color semiconductor light emitting element even if the sealing resin contains no phosphor. In addition, the blue-color semiconductor light emitting element, the green-color semiconductor light emitting element and the red-color semiconductor light emitting element are preferably provided equal in number to one another.

### Second Embodiment

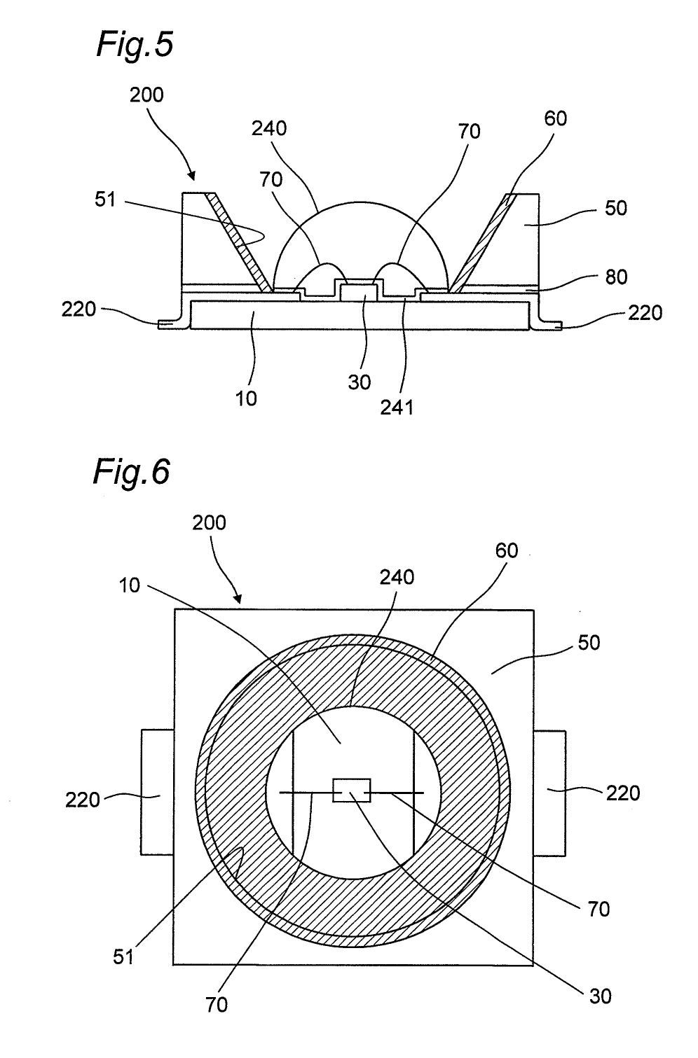

FIG. 5 shows a schematic sectional view of a surface-mount type light emitting device 200 according to a second embodiment of the invention, as it is cut by a plane vertical to the surface of the substrate 10. FIG. 6 shows a schematic view of the surface-mount type light emitting device 200 as viewed from above.

The surface-mount type light emitting device 200, as shown in FIGS. 5 and 6, includes interconnect patterns 220 and a dome-shaped phosphor-containing sealing resin 240. These interconnect patterns 220 differ only in shape from the interconnect patterns 20 of the first embodiment. In addition, the dome-shaped phosphor-containing sealing resin 240 is an example of the sealing resin of the invention.

A lower portion of the dome-shaped phosphor-containing sealing resin 240 is a phosphor-containing layer 241 containing a phosphor (not shown). Portions of the dome-shaped phosphor-containing sealing resin 240 other than the lower portion contain no phosphor and are transparent to emitted light wavelengths of the semiconductor light emitting element 30.

According to the surface-mount type light emitting device 200 having the above-described construction, since the dome-shaped phosphor-containing sealing resin 240 has the phosphor-containing layer 241 in the lower portion, wavelength conversion efficiency by the phosphor can be improved.

### Third Embodiment

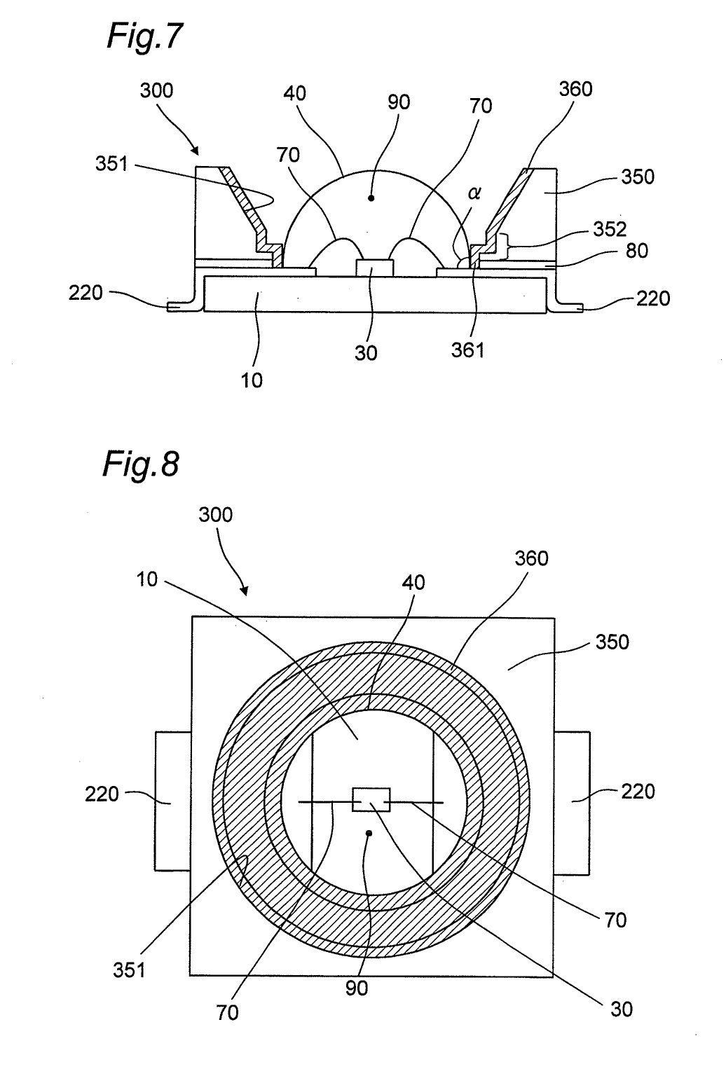

FIG. 7 shows a schematic sectional view of a surface-mount type light emitting device 300 according to a third embodiment of the invention, as it is cut by a plane vertical to the surface of the substrate 10. FIG. 8 shows a schematic view of the surface-mount type light emitting device 300, as viewed from above.

The surface-mount type light emitting device 300 includes a reflector 350 and a liquid-repelling layer 360.

The reflector 350 is attached to the substrate 10 and has an opening 351 overlapping with the semiconductor light emitting element 30 in a plan view. A step gap portion 352 is provided at a lower end portion of the inner wall of the opening 351. This step gap portion 352 is composed of a first cylindrical surface extending in a thicknesswise direction of the substrate 10, an annular surface having an inner circumferential edge adjoining an upper end of the first cylindrical surface, and a second cylindrical surface which has a lower end adjoining the outer circumferential edge of the annular surface and which extends in a thicknesswise direction of the substrate 10.

The liquid-repelling layer 360 is provided so as to cover the inner wall of the opening 351 of the reflector 350. As a result of this, a step gap portion corresponding to the step gap portion 352 is formed also at a lower portion of the inner surface of the liquid-repelling layer 360. Then, an inner surface of the lower end portion 361 of the liquid-repelling layer 360 extends in the thicknesswise direction of the substrate 10. That is, the inner surface of the lower end portion 361 of the liquid-repelling layer 360 is vertical to the surface of the substrate 10. The inner surface of the lower end portion 361 of the liquid-repelling layer 360 is in contact with the foot portion of the dome-shaped phosphor-containing sealing resin 40. It is noted that the inner surface of the lower end portion 361 of the liquid-repelling layer 360 may be generally vertical to the surface of the substrate 10.

According to the surface-mount type light emitting device 300 having the above-described construction, since the inner surface of the lower end portion 361 of the liquid-repelling layer 360 is vertical to the surface of the substrate 10, an angle a of a foot-portion side face of the dome-shaped phosphor-containing sealing resin 40 to a bottom surface (substrate 10 side surface) of the dome-shaped phosphor-containing sealing resin 40 can easily be set to 90° or nearly 90°.

Accordingly, by surface tension of the dome-shaped phosphor-containing sealing resin 40, the dome-shaped phosphor-containing sealing resin 40 can be made to serve as a resin lens of high curvature.

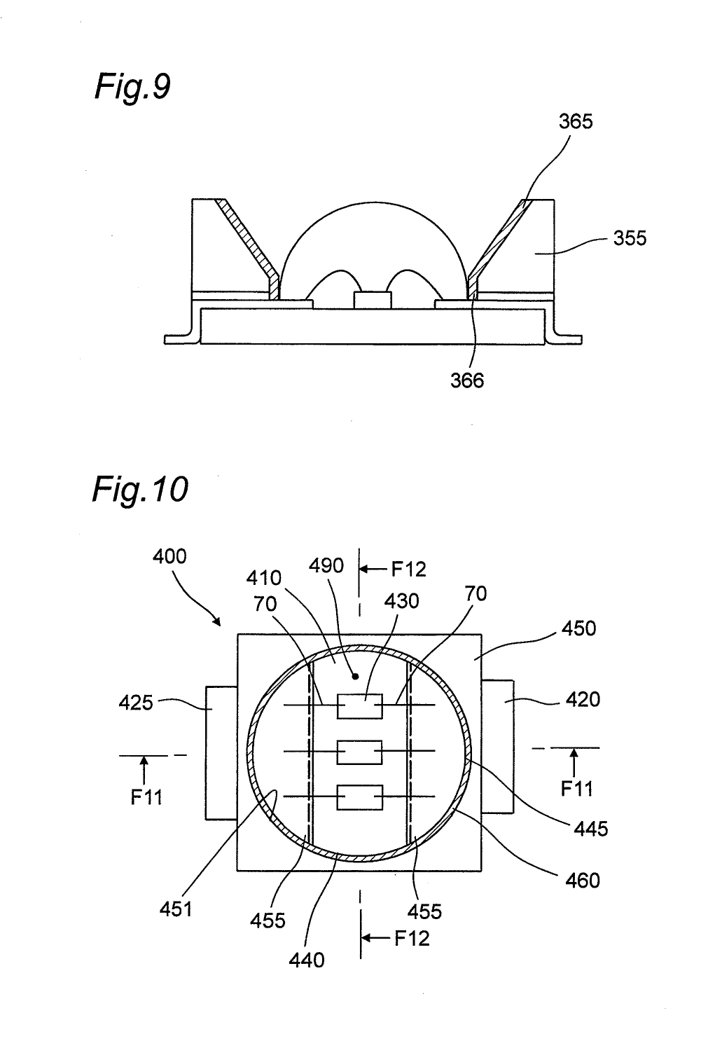

In this third embodiment, the reflector 350 and the liquid-repelling layer 360 may be substituted with a reflector 355 and a liquid-repelling layer 365 shown in FIG. 9. The inner surface of a lower end portion 366 of the liquid-repelling layer 365 is vertical or generally vertical to the surface of the substrate 10. As a result, even with the liquid-repelling layer 365, functional effects similar to those of the liquid-repelling layer 360 can be obtained.

### Fourth Embodiment

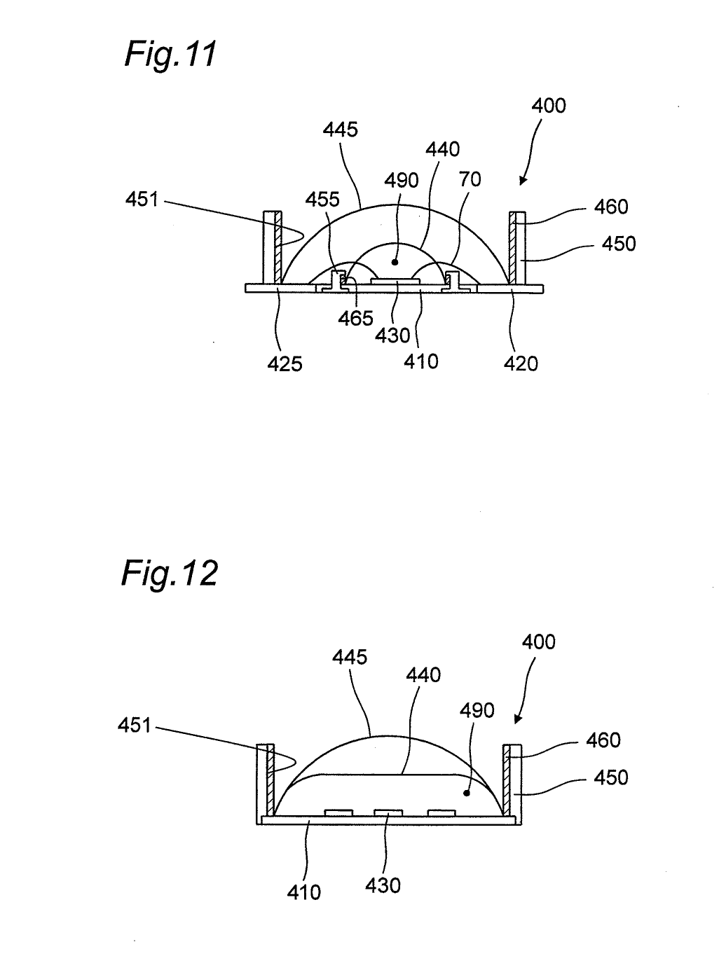

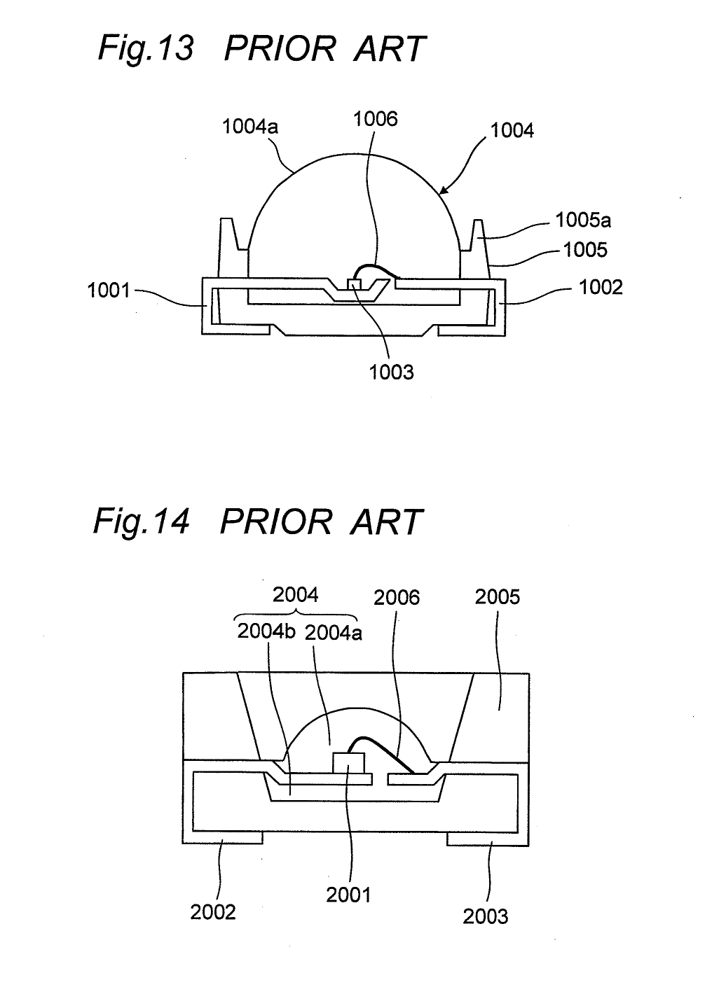

FIG. 10 shows a schematic view of a surface-mount type light emitting device 400 according to a fourth embodiment of the invention, as viewed from above. FIG. 11 shows a schematic sectional view taken along the line F11-F11 of FIG. 10. Further, FIG. 12 shows a schematic sectional view taken along the line F12-F12 of FIG. 10.

The surface-mount type light emitting device 400, as shown in FIGS. 10 to 12, includes: a substrate 410; a metallic anode electrode 420 fixed to one side portion of the substrate 410; a metallic cathode electrode 425 fixed to the other side portion of the substrate 410; three semiconductor light emitting elements 430 mounted on the substrate 410; a dome-shaped phosphor-containing sealing resin 440 for sealing the three semiconductor light emitting elements 430; a dome-shaped light-pervious sealing resin 445 provided on the dome-shaped phosphor-containing sealing resin 440; a first reflector 450 which is attached to the substrate 410 and which has an opening 451 overlapping with the semiconductor light emitting element 430 in a plan view; a second reflector 455 which is attached to the substrate 410 and which is positioned inside the first reflector 450; a first liquid-repelling layer 460 which covers the inner wall surface of the opening 51 of the first reflector 450; and a second liquid-repelling layer 465 which covers one surface of the second reflector 455 on one side closer to the semiconductor light emitting elements 430. It is noted that the anode electrode 420 and the cathode electrode 425 are one example of the interconnect patterns of the invention. Also, the dome-shaped phosphor-containing sealing resin 440 and the dome-shaped light-pervious sealing resin 445 are one example of the sealing resin of the invention.

The substrate 410 is formed from, for example, ceramics into a platy shape. Recess portions are provided at both side portions of the substrate 410, respectively. Most part of the anode electrode 420 is fitted into a recess portion on one side portion of the substrate 410. Also, most part of the cathode electrode 425 is fitted into the other side portion of the substrate 410. Rear faces of the three semiconductor light emitting elements 430, respectively, are adhesively fixed to the surface of the substrate 410.

Each of the semiconductor light emitting elements 430, which is an ultraviolet LED chip (emission wavelength: 360 nm), is connected to the anode electrode 420 and the cathode electrode 425 via the wire 70.

The dome-shaped phosphor-containing sealing resin 440 holds phosphor 490 (only one piece is shown in each of FIGS. 10 to 12) dispersed uniformly. Also, since the second liquid-repelling layer 465 is provided between the dome-shaped phosphor-containing sealing resin 440 and the second reflector 455, the dome-shaped phosphor-containing sealing resin 440 is not in contact with the second reflector 455. The phosphor 490, which is excited by emitted light of the semiconductor light emitting element 430, emits light of green and red-related colors, or yellow-green related colors, or yellow-green and red-related colors.

The dome-shaped light-pervious sealing resin 445, which contains no phosphor, has a generally hemispherical surface. Also, although the dome-shaped light-pervious sealing resin 445 is in contact with the second reflector 455, yet the second liquid-repelling layer 465 is provided between the dome-shaped light-pervious sealing resin 445 and the first reflector 450, so that the dome-shaped light-pervious sealing resin 445 is not in contact with the first reflector 450.

The first reflector 450 is bonded to the substrate 410, the anode electrode 420 and the cathode electrode 425 by an unshown adhesive material. Also, the inner wall surface of the opening 451 of the first reflector 450 is a cylindrical surface.

The second reflector 455, is provided in two arrays so as to sandwich the three semiconductor light emitting elements 430, extends parallel to an extending direction of the three semiconductor light emitting elements 430. An upper end portion of the second reflector 455 is bent toward the semiconductor light emitting elements 430.

The first liquid-repelling layer 460 is provided so as to cover the inner wall surface of the opening 451 of the first reflector 450. Also, the lower end portion of the first liquid-repelling layer 460 is in contact with the foot portion of the dome-shaped light-pervious sealing resin 445.

The second liquid-repelling layer 465 is provided so as to cover one surface of the second reflector 455 on one side closer to the semiconductor light emitting elements 430. Also, the lower end portion of the second liquid-repelling layer 465 is in contact with the foot portion of the dome-shaped phosphor-containing sealing resin 440.

According to the surface-mount type light emitting device 400 having the above-described construction, since the first reflector 450, the second reflector 455, the first liquid-repelling layer 460 and the second liquid-repelling layer 465 are included therein, the dome-shaped light-pervious sealing resin 445 can be formed on the dome-shaped phosphor-containing sealing resin 440 without being affected by the second liquid-repelling layer 465.

Although the phosphor 490 is held uniformly dispersed in the dome-shaped phosphor-containing sealing resin 440 in this fourth embodiment, yet the phosphor 490 may also be settled near the semiconductor light emitting elements 430.

Use of PTFE as the material of the first liquid-repelling layer 460 and the second liquid-repelling layer 465 in the fourth embodiment is preferable because deteriorations of the first reflector 450 and the second reflector 455 due to ultraviolet rays can be reduced.

In the first to fourth embodiments, a liquid-repelling layer which is entirely in contact with the sealing resin may also be used.

In the first to fourth embodiments, a reflector working also as a substrate, which is fabricated by etching an insulative block material as an example, may also be used as an example of the substrate and the reflector of the invention.

The present invention is not limited to the above-described first to fourth embodiments, and may be changed and modified in various ways within the scope of the invention. For example, combining the first to fourth embodiments as required may be applied as an embodiment of the invention.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### REFERENCE SIGNS LIST

10, 410 substrate
20, 220 interconnect pattern
30, 430 semiconductor light emitting element
40, 240, 440 dome-shaped phosphor-containing sealing resin
50, 350, 355 reflector
51, 351, 451 opening
60, 360, 365 liquid-repelling layer
70 wire
80 adhesive sheet
90, 490 phosphor
100, 200, 300, 400 surface-mount type light emitting device
241 phosphor-containing layer
352 step gap portion
361, 366 lower end portion
420 anode electrode
425 cathode electrode
445 dome-shaped light-pervious sealing resin
450 first reflector
455 second reflector
460 first liquid-repelling layer
465 second liquid-repelling layer

### CITATION LIST

Patent Literature

Patent Literature 1: JP 2002-223005 A (FIG. 6)

Patent Literature 2: JP 2005-317661 A (FIG. 5)

1. A light emitting device comprising:
a substrate;
an interconnect pattern provided on the substrate;
a semiconductor light emitting element mounted on the substrate and electrically connected to the interconnect pattern;
a sealing resin for sealing the semiconductor light emitting element;
a reflector provided on the substrate and having an opening which overlaps with the semiconductor light emitting element in a plan view; and
a liquid-repelling layer which covers an inner wall surface of the opening of the reflector and at least part of which is in contact with the sealing resin.

2. The light emitting device as claimed in claim 1, wherein
an end-portion inner surface of the liquid-repelling layer on one side closer to the substrate is vertical or generally vertical to one surface of the substrate closer to the semiconductor light emitting element, and is in contact with a peripheral edge portion of the sealing resin.

3. The light emitting device as claimed in claim 1, wherein
the sealing resin includes at least one of a light-pervious resin which is pervious to emitted light of the semiconductor light emitting element and a resin containing a phosphor.

4. The light emitting device as claimed in claim 1, wherein
the liquid-repelling layer is formed from a fluorine-based resin.

5. The light emitting device as claimed in claim 1, wherein
the sealing resin is surrounded by the liquid-repelling layer.

6. The light emitting device as claimed in claim 1, wherein
the liquid-repelling layer has a first liquid-repelling layer, a second liquid-repelling layer provided between the first liquid-repelling layer and the semiconductor light emitting element.

7. The light emitting device as claimed in claim 2, wherein
the liquid-repelling layer has a first liquid-repelling layer, a second liquid-repelling layer provided between the first liquid-repelling layer and the semiconductor light emitting element.

8. The light emitting device as claimed in claim 3, wherein
the liquid-repelling layer has a first liquid-repelling layer, a second liquid-repelling layer provided between the first liquid-repelling layer and the semiconductor light emitting element.

9. The light emitting device as claimed in claim 4, wherein
the liquid-repelling layer has a first liquid-repelling layer, a second liquid-repelling layer provided between the first liquid-repelling layer and the semiconductor light emitting element.

10. The light emitting device as claimed in claim 5, wherein
the liquid-repelling layer has a first liquid-repelling layer, a second liquid-repelling layer provided between the first liquid-repelling layer and the semiconductor light emitting element.
